(19) United States
(12) Patent Application Publication
(10) Pub. No.: US 2025/0078342 A1
(43) Pub. Date: Mar. 6, 2025

(54) RECONSTRUCTION NETWORK AND METHOD FOR RECONSTRUCTING CINE MRI IMAGES

(71) Applicant: Siemens Healthineers AG, Forchheim (DE)

(72) Inventors: Marc VORNEHM, Erlangen (DE); Jens WETZL, Erlangen (DE); Daniel GIESE, Erlangen (DE); Florian KNOLL, Erlangen (DE)

(73) Assignee: Siemens Healthineers AG, Forchheim (DE)

(21) Appl. No.: 18/820,939

(22) Filed: Aug. 30, 2024

(30) Foreign Application Priority Data
Sep. 4, 2023 (EP) 23195170.8

(51) Int. Cl. G06T 11/00

(52) U.S. Cl. CPC G06T 11/006; G06T 2210/41; G06T 2211/441

(57) ABSTRACT

The reconstruction network is a variational network configured to reconstruct images from cine MRI data. The reconstruction network comprises an architecture with a cascade of cascade modules. The input of the first cascade module is an input-stack of a plurality of N frames and the input of each following cascade module is the input-stack and an output-stack of the preceding cascade module. The reconstruction network further includes a selection unit configured to select a single frame being processed by the cascade modules that corresponds to the i-th frame of the input stack as the basis for the output dataset.

### CROSS-REFERENCE TO RELATED APPLICATION(S)

The present application claims priority under 35 U.S.C. § 119 to European Patent Application No. 23195170.8, filed Sep. 4, 2023, the entire contents of which are incorporated herein by reference.

### FIELD

One or more embodiments of the present invention describe a reconstruction network and a reconstruction-method for reconstructing cine MRI images, as well as training-method for training the reconstruction network and an MRI-System. Especially, one or more embodiments of the present invention pertain to low-latency deep learning-based reconstruction of interactive real-time (preferably cardiac) cine MRI.

### BACKGROUND

Cine MRI, also known as “cine sequences” or “cine imaging”, is a type of MRI recording to capture motion. Cine images are acquired by repeatedly imaging an area of interest for a certain period of time. Typically, a single slice is recorded, although it is also possible to record 3D images.

Cine MRI is often used for cardiac imaging. Interactive cardiac MRI is commonly used for real-time diagnostic as well as interventional applications and poses unique requirements on reconstruction latency, i.e. the time between acquisition and image display.

For device navigation, for instance, a maximum latency of 200 ms is considered tolerable. Achieving the desired spatial and temporal resolution often requires high acceleration rates, which, in turn, call for sophisticated and time-consuming reconstruction techniques.

### SUMMARY

It is an object of one or more embodiments of the present invention to improve the known systems and methods to facilitate an improvement in reconstructing cine MRI images with a trained (machine learning) reconstruction network. Especially, it is an object of one or more embodiments of the present invention to provide a solution for low-latency deep learning-based reconstruction of interactive real-time (preferably cardiac) cine MRI.

At least this object is achieved by a reconstruction network, a reconstruction-method, a training-method and an MRI-System according to the embodiments and as claimed.

A (machine learning) reconstruction network, according to an embodiment of the present invention, for reconstructing cine MRI images is a variational network designed for reconstructing images from cine MRI data and comprising an architecture with a cascade of (especially serially arranged) cascade-modules. Each cascade module resembles one update step in an iterative gradient descent-based reconstruction. The input of the first cascade-module is an input-stack of a plurality of N frames and the input of each following cascade-module is the input-stack and an output-stack of the preceding cascade-module. The reconstruction network (additionally) comprises a selection-unit designed to select one single frame being processed by the cascade-modules that corresponds to the i-th frame of the input stack for being the basis for the output dataset (reconstructed images or frames in k-space).

The general architecture of a variational network as well as suitable training procedures are well known in the art. The reconstruction network, according to an embodiment of the present invention, must be able to reconstruct cine MRI images, i.e. images from undersampled MRI-datasets (being k-space frames). The internal architecture of the reconstruction network is a cascade of cascade-modules that are serially arranged (the input of each following cascade-module is the output-stack of the preceding cascade-module). Thus, each cascade module resembles one update step in an iterative gradient descent-based reconstruction. The input of the first cascade-module is an input-stack of a plurality of N (k-space) frames.

Preferably, the number of serially arranged cascade-modules lies between 2 and 20, especially between 5 and 10. More cascade-modules may improve reconstruction quality, but also increase reconstruction time. The inventors found out that increasing the model complexity beyond 6-8 cascade-modules does not substantially improve image quality.

The input of each cascade-module is preferably also coil sensitivity maps. The cascade modules may have identical internal architectures, but different weighting factors and/or computing parameters.

One very important feature of the reconstruction network, according to an embodiment of the present invention, is the selection-unit that is designed to select one single frame (being an output of the last cascade) that corresponds to the i-th frame of the input stack. This means that the selected frame is different to the inputted frames, since it has been processed by the cascade, but is has always the same position concerning the input-stack (e.g. always the last frame).

This frame is then the basis for the output dataset. The output dataset may comprise reconstructed images and/or frames in k-space. Since the variational network could use image information of the whole stack of frames, showing a scene, e.g. such as a beating heart, the quality of the single frame and, thus, also the quality of an image reconstructed from that single frame is enhanced by reconstruction network.

A reconstruction-method, according to an embodiment of the present invention, for reconstructing cine MRI images with a reconstruction network, according to an embodiment of the present invention, comprising the following steps:
a) recording a plurality of MRI dataframes from a region of interest at different points of time, especially from a heart,
b) form an input stack from the temporally last recorded plurality of N MRI dataframes,
c) inputting the input-stack into the reconstruction network and reconstructing an image from one single frame chosen by the selection-unit of the reconstruction network (i.e. processed by the cascade modules of the reconstruction network and corresponding to the i-th frame of the input stack),
d) displaying the image,
e) in the case there is another recorded MRI dataframe, repeating the steps b) to e) until a termination condition is reached.

The recording of a plurality of MRI dataframes from a region of interest at different points of time is well known. Usually (at least in cine MRI), these datasets are under-sampled in order to record datasets fast enough to show a moving ROI (a video). The reconstruction-method is especially advantageous for cardiac MRI.

The input stack is formed in a similar manner as explained above for the training-frames. In order to have a small latency, the input stack should be selected from the temporally last recorded N MRI dataframes. The number of frames of the input stack should be the same as the number of training-frames, since the reconstruction network has been trained for this very number.

This input stack could simply be inputted into a (trained) reconstruction network that will reconstruct an image from a single frame of the input stack automatically, and this image can then be displayed.

In order to produce a video, every time there is another recorded MRI dataframe, there could be generated a new stack for every repetition or the oldest frame could be deleted a one end and the newest frame could be added to the other end of this stack. With the new input frames, a new image could be reconstructed. Displaying the reconstructed images will result in a video. Since the time for reconstruction is very short, the video shows the recorded ROI nearly in real time.

A training-method, according to an embodiment of the present invention, is able to train a (machine learning) reconstruction network, according to an embodiment of the present invention, for reconstructing cine MRI images. The reconstruction network is preferably a deep machine learning network and the training-method is then a deep learning-based method for real-time reconstruction of (especially cardiac) cine MRI. Its goal is to reduce reconstruction latency and enhance image quality, especially to assess its feasibility for interactive real-time (IRT) MRI applications. The training-method comprises the following steps:
a) recording a plurality of MRI dataframes in a time period, wherein the MRI dataframes show a region of interest at different points of time,
b) selecting a subset of N training-frames consecutive in time from the MRI dataframes as input-stack,
c) inputting the subset of training-frames into the reconstruction network and generating an output dataset based on one single frame chosen by the selection-unit of the reconstruction network (i.e. a frame processed by the cascade modules of the reconstruction network and corresponding to the i-th frame of the input stack),
d) computing the loss based on the output dataset and update the parameters of the reconstruction network based on this loss,
e) selecting a further subset of N training-frames consecutive in time from the MRI dataframes,
f) repeating the steps c) to f) until a termination condition is reached.

Variational Networks are well known and actually used for reconstructing images from MRI dataframes. Since the technical field is cine MRI, these MRI dataframes are datasets of an MRI recording taken at certain points in time. Although a frame may comprise data from a 3D-area, it is often just data from a slice of the region of interest (ROI).

Thus, each MRI dataframe could be imagined as k-space data which (when an image would be reconstructed from it) shows at least a slice of the ROI. Now, many frames are recorded in a time period, wherein every frame could be imagined as representing a slice. Since the region of interest may change in time, it is not necessary that all frames represent the same position of a slice in patient. However, they always represent a part of the recorded region. For example, the frames may “show” (they are in k-space) a beating heart, wherein every frame “shows” another state of the heartbeat. The frames may also follow the path of an instrument “showing” different slices of the patient depending on where the tip of the instrument is positioned at a point in time. Thus, the MRI dataframes could be imagined (when reconstructed) as a movie of a region of interest (e.g. a certain slice of the heart).

After the MRI dataframes are recorded, the subset of N training-frames is selected from these MRI dataframes. The training-frames must be consecutive in time (i.e. a series of temporally adjacent dataframes), but it is not necessary that they comprise the newest or oldest MRI dataframe. Usually, not all MRI dataframes are fetched, but only a (small) part (N is preferably smaller than the total number of MRI dataframes. It is not necessary to stop the recording of MRI dataframes for this step.

These training-frames are then inputted into the reconstruction network and an output dataset is generated. This output dataset could be an image reconstructed from one single frame selected by the selection-unit (then the loss is calculated based on that image). The output dataset could also be the selected single training-frame (then the loss could be calculated directly in k-space).

It should be noted that it is not necessary to reconstruct other images or to select other single frames, since the aim of the training-method is to get optimal data for one single frame for each input stack.

It is preferred that the relative position of the selected single frame stays the same for all sets of training-frames during the training. The selected single frame may correspond to the last of the N training-frames, but could also correspond to the second last or the third last. The position of the selected single frame could be selected depending on the latency that is tolerated. When there are some frames following the selected single frame, “future” states could be regarded to enhance accuracy of the reconstruction (there are some frames “showing” the past and some “showing” the future of the selected training-frame). On the other hand, when the last frame is selected as single frame, the latency will be minimal. Since in typical applications, the latency could be about 200 ms, it could be advantageous, to select a single frame that is temporally positioned in the last 200 ms of the N training-frames. In short: By delaying the reconstruction by one frame or two, the network can incorporate future information, which further improves image quality at the expense of increased reconstruction latency.

Based on the output dataset (this single frame or an image reconstructed from it), the loss of this image is calculated and the parameters of the reconstruction network are updated based on this loss (i.e. the loss is propagated back into the network). The construction of such loss as well in image space as in k-space, and the updating of parameters is well known in the art and belongs to a typical training procedure. However, in this training-method, the loss is calculated (exclusively) based on the single frame (e.g. from this very frame or an image reconstructed from that frame) and not on a plurality of frames.

As said above, a typical variational network comprises several cascades of machine networks, e.g. a convolutional Network combined with a consistency module. The goal of the training is to find an optimal parameter set of these cascades that may have an identical architecture, but different parameter-values. Typically, a loss function has to be minimized over the single image with respect to the parameters. The loss function typically defines the similarity between the reconstructed image and a reference image that should have a good quality. For example, the data used to generate the training data could be normally recorded MRI-data of good quality (for training the recording time is not crucial). The reference image could be reconstructed from this “good” data. The training-datasets could now be undersampled sets of this “good” data. Then, there is a clean, artifact-free reference image. The loss function could be the mean-squared error (MSE-loss), the SSIM-Loss (SSIM for structural similarity index measure”) or the so called “™-loss” the symmetric loss function for magnetic resonance imaging reconstruction and image registration with deep learning.

Since the complete training-dataset is inputted into the variational network, information of all frames are present in a single frame outputted by the variational network. One could say that a frame is ameliorated with the information of the preceding and possibly following frames. Thus, the quality of the single frame selected is better than the quality of the respective training-frame of the inputted training dataset. The feature that the output dataset is based on a single frame selected from the subset of training-frames, therefore means that one frame at a defined position of the stack of frames of the training-dataset is chosen. The respective single frame of the outputted stack is then chosen as output dataset. Although this single frame corresponds to the inputted training-frame (i.e. shows the same object at the same time, e.g. the same phase of a heartbeat) it comprises information of the whole stack of the inputted training-dataset.

Then, a further subset of N training-frames is selected and the training is continued. It is especially possible to record MRI datasets over a (long) time period and always replace the oldest training-frame deleted at the “past temporal end” of the N training-frames by the newest MRI dataframe copied at the “future temporal end” of the N training-frames.

It should be noted that in the case where the loss is computed directly in k-space, the reconstruction network does not need to directly reconstruct images during training. It is not necessary that the reconstruction module of the reconstruction network is trained, since a known reconstruction module for the last image could be used. However, when the loss is calculated from a reconstructed image, the reconstruction module is already there.

In easy words, the reconstruction network is trained to output a video stream from an acquired MRI dataset. When using a temporally sliding window for selecting a subset of N frames from recorded MRI data, the reconstructed (single) images would show a moving scene. Due to the training the reconstruction can be optimized even if the MRI dataset is undersampled (see further description).

Especially this trained reconstruction network is advantageous for the reconstruction of interactive real-time (IRT) cardiac cine MRI. Its performance in terms of reconstruction time and quality is evaluated in the described “retrospective simulation” of an IRT scenario that would require low reconstruction latencies due to the trained network that could provide an output in a very short time.

It should be noted that for training this “sliding window” is not absolutely necessary, since the reconstruction works for single images.

An MRI-System, according to an embodiment of the present invention, comprises a reconstruction network, according to an embodiment of the present invention, especially trained by a training-method according to an embodiment of the present invention.

It should be noted that a reconstruction network is preferably trained with the selection unit adjusted to select the single frame always with the same position (the i-th) corresponding to the frames of the input stack. However, when a video with more or less latency is desired, the position of the selected frame has to be changed. Looking at these specially trained reconstruction networks it is preferred that there are multiple reconstruction networks all been trained for a different position of the selected single frame. For this embodiment, the MRI-system preferably comprises a controller and/or means for controlling the selection unit or for choosing a reconstruction network.

The control of the selection unit may be a control at the beginning of training. The position of the single frame could be selected. After the selection it is preferred that the selected position is not changeable any more for this reconstruction network (e.g. written in an EPROM).

A preferred embodiment of the MRI-System, comprises multiple reconstruction networks, according to an embodiment of the present invention, with selection units designed to select single frames at different positions of processed stacks, wherein each reconstruction network comprises a selection unit selecting single frames at an individual constant position of processed stacks (not changeable, always stays the same).

It is preferred that the MRI-System additionally comprises a user interface designed such that a user is able to choose between the positions of the selected single frames, especially by choosing between given positions or between given latency times.

Some units or modules of, according to embodiments of the present invention, mentioned above can be completely or partially realized as software modules running on a processor of a computing system. A realization largely in the form of software modules can have the advantage that applications already installed on an existing computing system can be updated, with relatively little effort, to install and run these units of the present application. At least an object of one or more embodiments of the present invention is also achieved by a non-transitory computer program product with a computer program that is directly loadable into the memory of a computing system, and which comprises program units to perform the steps of the methods, at least those steps that could be executed by a computer, when the program is executed by the computing system. In addition to the computer program, such a computer program product can also comprise further parts such as documentation and/or additional components, also hardware components such as a hardware key (dongle etc.) to facilitate access to the software.

A tangible or non-transitory computer readable medium such as a memory stick, a hard-disk or other transportable or permanently-installed carrier can serve to transport and/or to store the executable parts of the computer program product so that these can be read from a processor unit of a computing system. A processor unit can comprise one or more microprocessors or their equivalents.

Particularly advantageous embodiments and features of embodiments of the present invention are given by the dependent claims, as revealed in the following description. Features of different claim categories may be combined as appropriate to give further embodiments not described herein.

According to a preferred reconstruction network, a (especially each) cascade-module comprises a convolutional neural network (CNN) designed to create output images from input images, especially a U-net or a V-net (in an arrangement where images are reconstructed from the processed frames as input images for the CNN). These images are processed by the convolutional neural network, especially by using a temporal and/or spatial convolution, and are converted into k-space frames afterwards. Temporal convolutions or combined temporal/spatial convolutions are advantageous, since they enable the use of data redundancy in the frames. Since input and output are in k-space, the architecture of a cascade module is such that a reconstruction module (k-space to image) is followed by the convolutional neural network that is again followed by an inverted reconstruction module (image to k-space).

Preferably, a (especially each) cascade-module additionally comprises a data consistency module working parallel to the convolutional neural network, wherein the outputs of the consistency module and the convolutional neural network are combined, especially together with the input.

A preferred reconstruction network comprises an image reconstruction-module, arranged to receive the selected single frame of the selection unit and reconstructing an image based on the selected single frame. It should be noted that the selected single frame is a frame processed by the cascade-modules of the reconstruction network.

A preferred reconstruction network comprises a loss-module arranged to receive the selected single frame of the selection unit and a reference frame (e.g. a high-quality frame of the scene shown by the selected single frame) and calculating a loss. This loss is based on a comparison between data based on the selected single frame and on the reference frame.

A preferred reconstruction network is especially trained by the method explained above. This means that the reconstruction network is trained according to the following steps:
a) recording a plurality of MRI dataframes in a time period, wherein the MRI dataframes show a region of interest at different points of time,
b) selecting a subset of N training-frames consecutive in time from the MRI dataframes as input-stack,
c) inputting the subset of training-frames into the reconstruction network and generating an output dataset based on one single frame chosen by the selection-unit of the reconstruction network (i.e. processed by the cascade and corresponding to the i-th frame of the input stack), d) computing the loss based on the output dataset and update the parameters of the reconstruction network based on this loss,
e) selecting a further subset of N training-frames consecutive in time from the MRI dataframes,
f) repeating the steps c) to f) until a termination condition is reached.

According to a preferred training-method, the MRI dataframes are under-sampled by a predefined factor F (e.g. 8-fold) and the subset of training-frames is selected from the under-sampled MRI dataframes. Since for training, a fast data acquisition is not crucial, “full” data could be acquired for the MRI dataframes and for generating training data, these “full” data frames could be under-sampled in order to simulate cine-MRI data. This has the advantage that the original not-under-sampled MRI dataframes (showing accurate images when reconstructed) could be used for a supervised training. It is preferred that a temporally varying under-sampling pattern is used for each frame. This is advantageous in order to simulate fluctuations in the acquired data.

According to a preferred training-method, for the subset of N training-frames, N is bigger than 4 and/or less than 30, preferably wherein N is chosen between 7 and 14. This has been shown a good trade-off between reconstruction accuracy and time used for this reconstruction.

According to a preferred training-method, the time difference between consecutive MRI dataframes is constant over the MRI data (i.e. the temporal resolution is constant) and preferably less than 1/10 second, especially less than 1/20 second. This allows a good temporal resolution. Alternatively or additionally, a predefined data sampling pattern allows combining data with different temporal resolutions, especially radial or spiral golden angle.

According to a preferred training-method, every selected single frame has the same relative position in the respective subset of N training-frames. This means that always e.g. the last frame is selected or the i-th last in the case some “future” frames should optimize the quality of the selected frame. Preferably, a frame from the temporally last third of the subset of N training-frames is selected, wherein it is preferred that there are not more than 5 frames temporally following the selected single frame, especially wherein the selected single frame temporally corresponds to the newest (last) frame in the subsample. As said above, by delaying the reconstruction by one frame or two, the network can incorporate future information, which further improves image quality at the expense of increased reconstruction latency.

According to a preferred training-method, the first selected subset of training-frames starts with a frame of the MRI dataframes, and following subsets of N training-frames start with the second frame of the respective preceding subset of training-frames. Thus, preferably the subset of N training-frames is selected by a temporally sliding window.

According to a preferred training-method, the reconstruction unit comprises a reconstruction module designed to reconstruct an image from the selected single frame, wherein the loss is computed based on a comparison between a reconstructed image of the MRI dataframes and the image reconstructed based on a respective selected single frame. As said above, the loss could be computed in k-space, however, to compute the loss in image-space could be advantageous. Here it should be noted that the information of the training-frames is changed during the propagation through the reconstruction network. Thus, the data used for reconstructing an image is not identical to the originally inputted training-frame however, the data nevertheless represents the respective selected single frame and is based on this frame.

It is preferred to calculate MSE-loss, SSIM-loss or so called “⊥-loss”, wherein a combination of SSIM-loss and ⊥-loss is preferred. MSE loss, referring to the mean squared error and the SSIM-Loss (SSIM for, “structural similarity index measure”) are well known in the art. Also, the symmetric loss function for magnetic resonance imaging reconstruction and image registration with deep learning (“⊥-Loss”) is well known.

In a preferred embodiment of the present invention, components of the reconstruction network are part of a data-network, wherein preferably the data-network and an MRI-System which provides image data) are in data-communication with each other, wherein the data-network preferably comprises parts of the internet and/or a cloud-based computing system, wherein preferably the reconstruction network is realized in this cloud-based computing system. For example, the components of the system are part of a data-network, wherein preferably the data-network and a medical imaging system which provides the image data are in communication with each other. Such a networked solution could be implemented via an internet platform and/or in a cloud-based computing system.

The methods may also include elements of “cloud computing”. In the technical field of “cloud computing”, an IT infrastructure is provided over a data-network, e.g. a storage space or processing power and/or application software. The communication between the user and the “cloud” is achieved via data interfaces and/or data transmission protocols.

In the context of “cloud computing”, in a preferred embodiment of the methods according to the present invention, provision of data via a data channel (for example a data-network) to a “cloud” takes place. This “cloud” includes a (remote) computing system, e.g. a computer cluster that typically does not include the user's local machine. This cloud can be made available in particular by the medical facility, which also provides the medical imaging systems. In particular, the image acquisition data is sent to a (remote) computer system (the “cloud”) via a RIS (Radiology Information System) or a PACS (Picture Archiving and Communication System).

The training-method, according to embodiments of the present invention, enables a training of a neural network for reconstruction of interactive real-time (especially cardiac) cine MRI, especially optimized regarding latency and image quality. A trained reconstruction model, according to an embodiment of the present invention, achieves good reconstruction results with little temporal blurring.

### BRIEF DESCRIPTION OF THE DRAWINGS

Other objects and features of the present invention will become apparent from the following detailed descriptions considered in conjunction with the accompanying drawings. It is to be understood, however, that the drawings are designed solely for the purposes of illustration and not as a definition of the limits of the present invention.

FIG. 1 shows a simplified MRI system according to an embodiment of the present invention.

FIG. 2 shows a training procedure of the state of the art.

FIG. 3 shows a reconstruction procedure of the state of the art,

FIG. 4 shows a reconstruction procedure of the state of the art.

FIG. 5 shows a training-method as well as a reconstruction-method according to an embodiment of the present invention.

FIG. 6 shows a reconstruction network according to an embodiment of the present invention.

In the diagrams, like numbers refer to like objects throughout. Objects in the diagrams are not necessarily drawn to scale.

### DETAILED DESCRIPTION

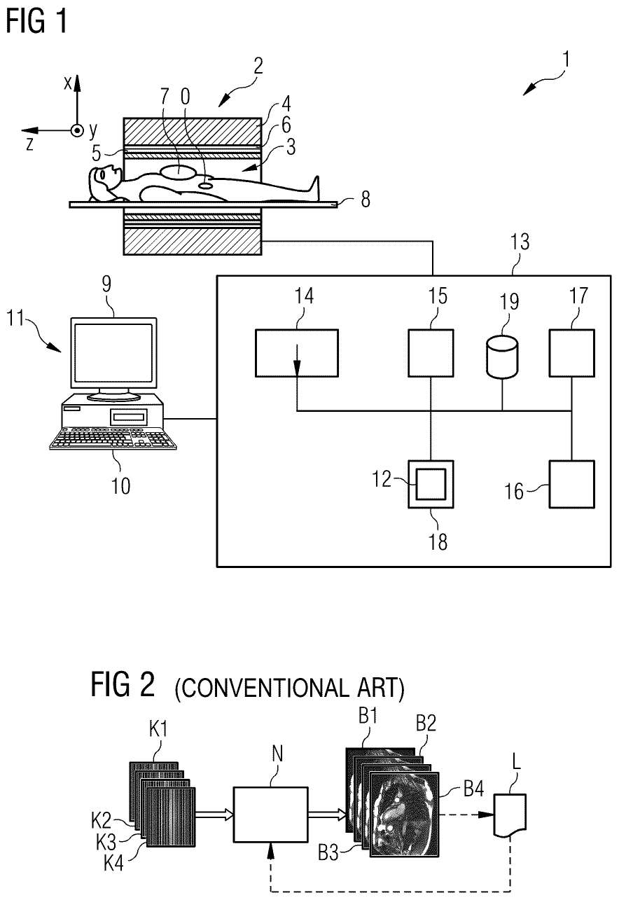

FIG. 1 shows a schematic representation of a magnetic resonance imaging system 1 (“MRI-system”). The MRI system 1 includes the actual magnetic resonance scanner (data acquisition unit) 2 with an examination space 3 or patient tunnel in which a patient or test person is positioned on a driven bed 8, in whose body the actual examination object is located.

The magnetic resonance scanner 2 is typically equipped with a basic field magnet system 4, a gradient system 6 as well as an RF transmission antenna system 5 and an RF reception antenna system 7. In the shown exemplary embodiment, the RF transmission antenna system 5 is a whole-body coil permanently installed in the magnetic resonance scanner 2, in contrast to which the RF reception antenna system 7 is formed as local coils (symbolized here by only a single local coil) to be arranged on the patient or test subject. In principle, however, the whole-body coil can also be used as an RF reception antenna system, and the local coils can respectively be switched into different operating modes.

The basic field magnet system 4 here is designed in a typical manner so that it generates a basic magnetic field in the longitudinal direction of the patient, i.e. along the longitudinal axis of the magnetic resonance scanner 2 that proceeds in the z-direction. The gradient system 6 typically includes individually controllable gradient coils in order to be able to switch (activate) gradients in the x-direction, y-direction or z-direction independently of one another.

The MRI system 1 shown here is a whole-body system with a patient tunnel into which a patient can be completely introduced. However, in principle the present invention can also be used at other MRI systems, for example with a laterally open, C-shaped housing, as well as in smaller magnetic resonance scanners in which only one body part can be positioned.

Furthermore, the MRI system 1 has a central control device 13 that is used to control the MRI system 1. This central control device 13 includes a sequence control unit 14 for measurement sequence control. With this sequence control unit 14, the series of radio-frequency pulses (RF pulses) and gradient pulses can be controlled depending on a selected pulse sequence or, respectively, a series of multiple pulse sequence to acquire magnetic resonance images within a measurement session. For example, such a series of pulse sequence can be predetermined within a measurement or control protocol. Different control protocols for different measurements or measurement sessions are typically stored in a memory 19 and can be selected by and operator (and possibly modified as necessary) and then be used to implement the measurement.

To output the individual RF pulses of a pulse sequence, the central control device 13 has a radio-frequency transmission device 15 that generates and amplifies the RF pulses and feeds them into the RF transmission antenna system 5 via a suitable interface (not shown in detail). To control the gradient coils of the gradient system 6, the control device 13 has a gradient system interface 16. The sequence control unit 14 communicates in a suitable manner with the radio-frequency transmission device 15 and the gradient system interface 16 to emit the pulse sequence.

Moreover, the control device 13 has a radio-frequency reception device 17 (likewise communicating with the sequence control unit 14 in a suitable manner) in order to acquire magnetic resonance signals (i.e. raw data) for the individual measurements, which magnetic resonance signals are received in a coordinated manner from the RF reception antenna system 7 within the scope of the pulse sequence.

A reconstruction unit 18 receives the acquired raw data and reconstructs magnetic resonance image data therefrom for the measurements. This reconstruction is typically performed on the basis of parameters that may be specified in the respective measurement or control protocol. For example, the image data can then be stored in a memory 19.

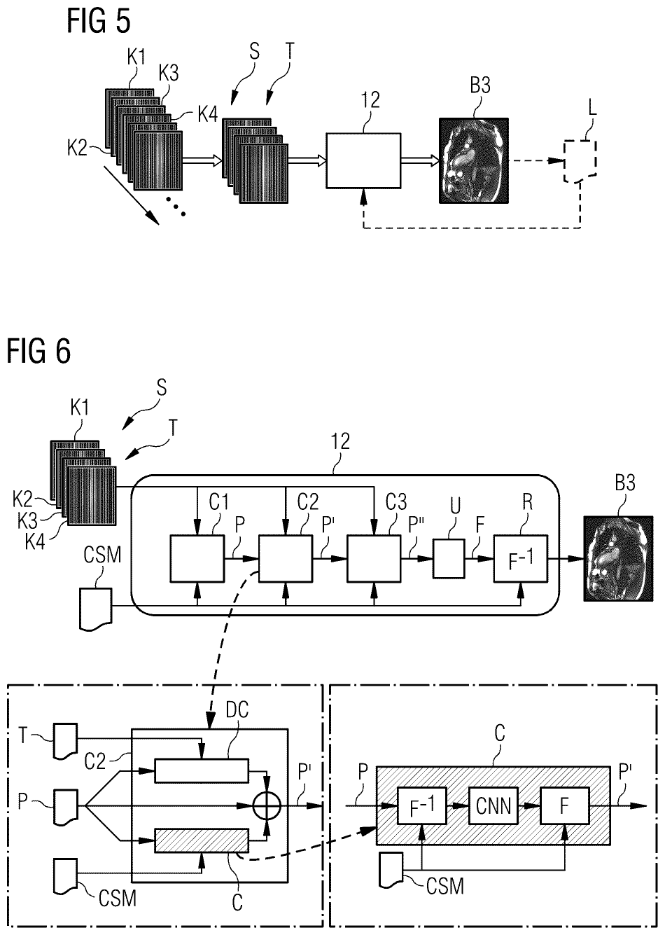

The reconstruction unit 18 comprises a trained reconstruction network 12 as e.g. shown in FIG. 6.

Operation of the central control device 13 can take place via a terminal 10 with an input unit and a display unit 9, via which the entire MRI system 1 can thus also be operated by an operator. MR images can also be displayed at the display unit 9, and measurements can be planned and started via the input unit (possibly in combination with the display unit 9), and in particular suitable control protocols can be selected (and possibly modified) with suitable series of pulse sequence PS as explained above.

The MRI system 1, according to an embodiment of the present invention, and in particular the control device 13, can have a number of additional components that are not shown in detail but are typically present at such systems, for example a network interface in order to connect the entire system with a network and be able to exchange raw data and/or image data or, respectively, parameter maps, but also additional data (for example patient-relevant data or control protocols).

The manner by which suitable raw data are acquired by radiation of RF pulses and the generation of gradient fields, and MR images are reconstructed from the raw data, is known to those skilled in the art and thus need not be explained in detail herein.

FIG. 2 shows a training procedure of the state of the art. At first, a plurality of N MRI dataframes K1, K2, K3, K4 is recorded from a region of interest at different points of time. Then, the stack is inputted into the neural network N to be trained. This neural network N reconstructs N images B1, B2, B3, B4. For training, a loss is calculated for all reconstructed images B1, B2, B3, B4 and the neural network N is updated based on this loss L.

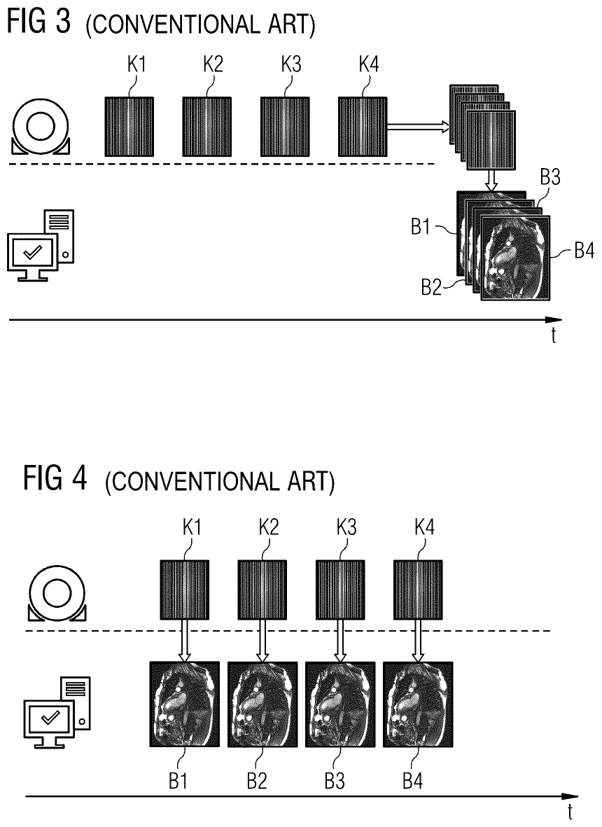

FIG. 3 shows a reconstruction procedure of the state of the art. Here, as shown in FIG. 2, MRI datasets K1, K2, K3, K4 being k-space data K1, K2, K3, K4 are recorded, a stack is produced and all images B1, B2, B3, B4 are reconstructed from this stack.

FIG. 4 shows a reconstruction procedure of the state of the art. Here, in contrast to FIG. 3, MRI datasets K1, K2, K3, K4 being k-space data K1, K2, K3, K4 are recorded and an image B1, B2, B3, B4 of every MRI dataset K1, K2, K3, K4 is reconstructed just after recording.

FIG. 5 shows a training-method as well as a reconstruction-method according to an embodiment of the present invention. The difference between training and reconstruction is that during training a loss L is produced and the parameters of the reconstruction network are updated (dashed arrow).

At first, a plurality of MRI dataframes K1, K2, K3, K4 is recorded from a region of interest at different points of time, especially from a heart. For training, stored datasets could be used, for clinical application, actually recorded frames should be used, at least when it is intended to show a “real-time” video.

From these MRI datasets K1, K2, K3, K4, a stack of frames is formed. For training, this is the training-stack T (the frames could artificially be under-sampled), for application it is the input stack S. Training-stack T and input stack S should comprise the same number of frames. Regarding a “real-time” video, the input stack S should comprise the temporally last recorded N MRI dataframes K1, K2, K3, K4. Regarding training it is only necessary that there are temporally consecutive frames.

Then, the stack is inputted into the reconstruction network 12.

For application, there is a reconstruction step, wherein an image B3 is reconstructed from a single frame of the input stack S. For training, this image B3 may be reconstructed from a single frame of the training-stack T, as well (as shown in this example), however, also pure k-space data could be used without any reconstruction.

This procedure is then repeated. For application, the reconstructed image B3 is displayed wherein due to displaying the actual image for many repetitions, a user may see a “real-time” video of the displayed images.

For training (following the dashed branch), the loss is calculated and the parameters of the reconstruction network are updated.

FIG. 6 shows a reconstruction network 12 for reconstructing cine MRI images according to an embodiment of the present invention. The reconstruction network 12 is a variational network designed for reconstructing images from cine MRI data and trained with a training-method according to FIG. 5.

The reconstruction network comprises an architecture with a cascade of (in this example) three serially arranged cascade-modules C1, C2, C3 each resembling one update step in an iterative gradient descent-based reconstruction. These three cascade-modules C1, C2, C3 each produce an output P, P′, P″ from an input T, P, P′ and are followed by a selection unit U, receiving the output P″ of the last cascade-module C3 and selecting one single frame F and an image reconstruction-module R, reconstructing an image B3 based on the selected single frame F (here always the third frame).

The input of the first cascade-module C1, C2, C3 is the subset of the training-frames T selected from the MRI dataset K1, K2, K3, K4 for training and the input data S from the MRI dataset K1, K2, K3, K4 for actual reconstruction work.

In this example, the input of each following cascade-module C1, C2, C3 is the subset of the training-frames T (upper arrows), the output P, P′ of the preceding cascade-module C1, C2 (center arrows) and also coil sensitivity maps (lower arrows). In this example the cascade modules have identical internal architectures as shown at the bottom, but different weighting factors and/or computing parameters.

As shown, each cascade-module C1, C2, C3 comprises a convolutional neural network CNN designed to create output images from input images, especially a U-net or a V-net. This convolutional neural network CNN gets its input data from a module (could be a reconstruction module R) generating images from k-space. Its output is back-transferred into k-space again by another module. Additionally, each cascade-module C1, C2, C3 comprises a data consistency module DC working parallel to the convolutional neural network CNN, wherein the outputs of the data consistency module DC and the convolutional neural network CNN are combined, especially together with the input.

A practical approach with a network of FIG. 6 and a method of FIG. 5 could be as follows: Fully sampled segmented cine acquisitions from an OCMR dataset (multi coil k-space data from fully sampled cardiac cine series) are retrospectively under-sampled by a factor of eight for constructing a training-dataset. For simulation of Interactive real-time MRI, the “sliding window” approach of the method is chosen, where a subset of eleven consecutive frames from one slice were reconstructed at a time. The loss was then computed on the i-th frame (e.g. the last or the third last) and propagated back into the network for optimization, where N is the size of the sliding window (here 11) and i ∈ [0, N [. Choosing not the last frame increases the latency but allows the network to not only rely on past information for reconstruction.

For the sake of clarity, it is to be understood that the use of “a” or “an” throughout this application does not exclude a plurality, and “comprising” does not exclude other steps or elements. The expression “a number of” means “at least one”. The mention of a “unit” or a “device” does not preclude the use of more than one unit or device. The expression “a number of” has to be understood as “at least one”.

Independent of the grammatical term usage, individuals with male, female or other gender identities are included within the term.

It will be understood that, although the terms first, second, etc. may be used herein to describe various elements, components, regions, layers, and/or sections, these elements, components, regions, layers, and/or sections, should not be limited by these terms. These terms are only used to distinguish one element from another. For example, a first element could be termed a second element, and, similarly, a second element could be termed a first element, without departing from the scope of example embodiments. As used herein, the term “and/or,” includes any and all combinations of one or more of the associated listed items. The phrase “at least one of” has the same meaning as “and/or”.

Spatially relative terms, such as “beneath,” “below,” “lower,” “under,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below,” “beneath,” or “under,” other elements or features would then be oriented “above” the other elements or features. Thus, the example terms “below” and “under” may encompass both an orientation of above and below. The device may be otherwise oriented (rotated 90 degrees or at other orientations) and the spatially relative descriptors used herein interpreted accordingly. In addition, when an element is referred to as being “between” two elements, the element may be the only element between the two elements, or one or more other intervening elements may be present.

Spatial and functional relationships between elements (for example, between modules) are described using various terms, including “on,” “connected,” “engaged,” “interfaced,” and “coupled.” Unless explicitly described as being “direct,” when a relationship between first and second elements is described in the disclosure, that relationship encompasses a direct relationship where no other intervening elements are present between the first and second elements, and also an indirect relationship where one or more intervening elements are present (either spatially or functionally) between the first and second elements. In contrast, when an element is referred to as being “directly” on, connected, engaged, interfaced, or coupled to another element, there are no intervening elements present. Other words used to describe the relationship between elements should be interpreted in a like fashion (e.g., “between,” versus “directly between,” “adjacent,” versus “directly adjacent,” etc.).

The terminology used herein is for the purpose of describing particular embodiments only and is not intended to be limiting of example embodiments. As used herein, the singular forms “a,” “an,” and “the,” are intended to include the plural forms as well, unless the context clearly indicates otherwise. As used herein, the terms “and/or” and “at least one of” include any and all combinations of one or more of the associated listed items. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. Expressions such as “at least one of,” when preceding a list of elements, modify the entire list of elements and do not modify the individual elements of the list. Also, the term “example” is intended to refer to an example or illustration.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

Unless otherwise defined, all terms (including technical and scientific terms) used herein have the same meaning as commonly understood by one of ordinary skill in the art to which example embodiments belong. It will be further understood that terms, e.g., those defined in commonly used dictionaries, should be interpreted as having a meaning that is consistent with their meaning in the context of the relevant art and will not be interpreted in an idealized or overly formal sense unless expressly so defined herein.

It is noted that some example embodiments may be described with reference to acts and symbolic representations of operations (e.g., in the form of flow charts, flow diagrams, data flow diagrams, structure diagrams, block diagrams, etc.) that may be implemented in conjunction with units and/or devices discussed above. Although discussed in a particularly manner, a function or operation specified in a specific block may be performed differently from the flow specified in a flowchart, flow diagram, etc. For example, functions or operations illustrated as being performed serially in two consecutive blocks may actually be performed simultaneously, or in some cases be performed in reverse order. Although the flowcharts describe the operations as sequential processes, many of the operations may be performed in parallel, concurrently or simultaneously. In addition, the order of operations may be re-arranged. The processes may be terminated when their operations are completed, but may also have additional steps not included in the figure. The processes may correspond to methods, functions, procedures, subroutines, subprograms, etc.

Specific structural and functional details disclosed herein are merely representative for purposes of describing example embodiments. The present invention may, however, be embodied in many alternate forms and should not be construed as limited to only the embodiments set forth herein.

In addition, or alternative, to that discussed above, units and/or devices according to one or more example embodiments may be implemented using hardware, software, and/or a combination thereof. For example, hardware devices may be implemented using processing circuitry such as, but not limited to, a processor, Central Processing Unit (CPU), a controller, an arithmetic logic unit (ALU), a digital signal processor, a microcomputer, a field programmable gate array (FPGA), a System-on-Chip (SoC), a programmable logic unit, a microprocessor, or any other device capable of responding to and executing instructions in a defined manner. Portions of the example embodiments and corresponding detailed description may be presented in terms of software, or algorithms and symbolic representations of operation on data bits within a computer memory. These descriptions and representations are the ones by which those of ordinary skill in the art effectively convey the substance of their work to others of ordinary skill in the art. An algorithm, as the term is used here, and as it is used generally, is conceived to be a self-consistent sequence of steps leading to a desired result. The steps are those requiring physical manipulations of physical quantities. Usually, though not necessarily, these quantities take the form of optical, electrical, or magnetic signals capable of being stored, transferred, combined, compared, and otherwise manipulated. It has proven convenient at times, principally for reasons of common usage, to refer to these signals as bits, values, elements, symbols, characters, terms, numbers, or the like.

It should be borne in mind that all of these and similar terms are to be associated with the appropriate physical quantities and are merely convenient labels applied to these quantities. Unless specifically stated otherwise, or as is apparent from the discussion, terms such as “processing” or “computing” or “calculating” or “determining” of “displaying” or the like, refer to the action and processes of a computer system, or similar electronic computing device/hardware, that manipulates and transforms data represented as physical, electronic quantities within the computer system's registers and memories into other data similarly represented as physical quantities within the computer system memories or registers or other such information storage, transmission or display devices.

In this application, including the definitions below, the term ‘module’ or the term ‘controller’ may be replaced with the term ‘circuit.’ The term ‘module’ may refer to, be part of, or include processor hardware (shared, dedicated, or group) that executes code and memory hardware (shared, dedicated, or group) that stores code executed by the processor hardware.

The module may include one or more interface circuits. In some examples, the interface circuits may include wired or wireless interfaces that are connected to a local area network (LAN), the Internet, a wide area network (WAN), or combinations thereof. The functionality of any given module of the present disclosure may be distributed among multiple modules that are connected via interface circuits. For example, multiple modules may allow load balancing. In a further example, a server (also known as remote, or cloud) module may accomplish some functionality on behalf of a client module.

Software may include a computer program, program code, instructions, or some combination thereof, for independently or collectively instructing or configuring a hardware device to operate as desired. The computer program and/or program code may include program or computer-readable instructions, software components, software modules, data files, data structures, and/or the like, capable of being implemented by one or more hardware devices, such as one or more of the hardware devices mentioned above. Examples of program code include both machine code produced by a compiler and higher level program code that is executed using an interpreter.

For example, when a hardware device is a computer processing device (e.g., a processor, Central Processing Unit (CPU), a controller, an arithmetic logic unit (ALU), a digital signal processor, a microcomputer, a microprocessor, etc.), the computer processing device may be configured to carry out program code by performing arithmetical, logical, and input/output operations, according to the program code. Once the program code is loaded into a computer processing device, the computer processing device may be programmed to perform the program code, thereby transforming the computer processing device into a special purpose computer processing device. In a more specific example, when the program code is loaded into a processor, the processor becomes programmed to perform the program code and operations corresponding thereto, thereby transforming the processor into a special purpose processor.

Software and/or data may be embodied permanently or temporarily in any type of machine, component, physical or virtual equipment, or computer storage medium or device, capable of providing instructions or data to, or being interpreted by, a hardware device. The software also may be distributed over network coupled computer systems so that the software is stored and executed in a distributed fashion. In particular, for example, software and data may be stored by one or more computer readable recording mediums, including the tangible or non-transitory computer-readable storage media discussed herein.

Even further, any of the disclosed methods may be embodied in the form of a program or software. The program or software may be stored on a non-transitory computer readable medium and is adapted to perform any one of the aforementioned methods when run on a computer device (a device including a processor). Thus, the non-transitory, tangible computer readable medium, is adapted to store information and is adapted to interact with a data processing facility or computer device to execute the program of any of the above mentioned embodiments and/or to perform the method of any of the above mentioned embodiments.

Example embodiments may be described with reference to acts and symbolic representations of operations (e.g., in the form of flow charts, flow diagrams, data flow diagrams, structure diagrams, block diagrams, etc.) that may be implemented in conjunction with units and/or devices discussed in more detail below. Although discussed in a particularly manner, a function or operation specified in a specific block may be performed differently from the flow specified in a flowchart, flow diagram, etc. For example, functions or operations illustrated as being performed serially in two consecutive blocks may actually be performed simultaneously, or in some cases be performed in reverse order.

According to one or more example embodiments, computer processing devices may be described as including various functional units that perform various operations and/or functions to increase the clarity of the description. However, computer processing devices are not intended to be limited to these functional units. For example, in one or more example embodiments, the various operations and/or functions of the functional units may be performed by other ones of the functional units. Further, the computer processing devices may perform the operations and/or functions of the various functional units without sub-dividing the operations and/or functions of the computer processing units into these various functional units.

Units and/or devices according to one or more example embodiments may also include one or more storage devices. The one or more storage devices may be tangible or non-transitory computer-readable storage media, such as random access memory (RAM), read only memory (ROM), a permanent mass storage device (such as a disk drive), solid state (e.g., NAND flash) device, and/or any other like data storage mechanism capable of storing and recording data. The one or more storage devices may be configured to store computer programs, program code, instructions, or some combination thereof, for one or more operating systems and/or for implementing the example embodiments described herein. The computer programs, program code, instructions, or some combination thereof, may also be loaded from a separate computer readable storage medium into the one or more storage devices and/or one or more computer processing devices using a drive mechanism. Such separate computer readable storage medium may include a Universal Serial Bus (USB) flash drive, a memory stick, a Blu-ray/DVD/CD-ROM drive, a memory card, and/or other like computer readable storage media. The computer programs, program code, instructions, or some combination thereof, may be loaded into the one or more storage devices and/or the one or more computer processing devices from a remote data storage device via a network interface, rather than via a local computer readable storage medium. Additionally, the computer programs, program code, instructions, or some combination thereof, may be loaded into the one or more storage devices and/or the one or more processors from a remote computing system that is configured to transfer and/or distribute the computer programs, program code, instructions, or some combination thereof, over a network. The remote computing system may transfer and/or distribute the computer programs, program code, instructions, or some combination thereof, via a wired interface, an air interface, and/or any other like medium.

The one or more hardware devices, the one or more storage devices, and/or the computer programs, program code, instructions, or some combination thereof, may be specially designed and constructed for the purposes of the example embodiments, or they may be known devices that are altered and/or modified for the purposes of example embodiments.

A hardware device, such as a computer processing device, may run an operating system (OS) and one or more software applications that run on the OS. The computer processing device also may access, store, manipulate, process, and create data in response to execution of the software. For simplicity, one or more example embodiments may be exemplified as a computer processing device or processor; however, one skilled in the art will appreciate that a hardware device may include multiple processing elements or processors and multiple types of processing elements or processors. For example, a hardware device may include multiple processors or a processor and a controller. In addition, other processing configurations are possible, such as parallel processors.

The computer programs include processor-executable instructions that are stored on at least one non-transitory computer-readable medium (memory). The computer programs may also include or rely on stored data. The computer programs may encompass a basic input/output system (BIOS) that interacts with hardware of the special purpose computer, device drivers that interact with particular devices of the special purpose computer, one or more operating systems, user applications, background services, background applications, etc. As such, the one or more processors may be configured to execute the processor executable instructions.

The computer programs may include: (i) descriptive text to be parsed, such as HTML (hypertext markup language) or XML (extensible markup language), (ii) assembly code, (iii) object code generated from source code by a compiler, (iv) source code for execution by an interpreter, (v) source code for compilation and execution by a just-in-time compiler, etc. As examples only, source code may be written using syntax from languages including C, C++, C#, Objective-C, Haskell, Go, SQL, R, Lisp, Java®, Fortran, Perl, Pascal, Curl, OCaml, Javascript®, HTML5, Ada, ASP (active server pages), PHP, Scala, Eiffel, Smalltalk, Erlang, Ruby, Flash®, Visual Basic®, Lua, and Python®.

Further, at least one example embodiment relates to the non-transitory computer-readable storage medium including electronically readable control information (processor executable instructions) stored thereon, configured in such that when the storage medium is used in a controller of a device, at least one embodiment of the method may be carried out.

The computer readable medium or storage medium may be a built-in medium installed inside a computer device main body or a removable medium arranged so that it can be separated from the computer device main body. The term computer-readable medium, as used herein, does not encompass transitory electrical or electromagnetic signals propagating through a medium (such as on a carrier wave); the term computer-readable medium is therefore considered tangible and non-transitory. Non-limiting examples of the non-transitory computer-readable medium include, but are not limited to, rewriteable non-volatile memory devices (including, for example flash memory devices, erasable programmable read-only memory devices, or a mask read-only memory devices); volatile memory devices (including, for example static random access memory devices or a dynamic random access memory devices); magnetic storage media (including, for example an analog or digital magnetic tape or a hard disk drive); and optical storage media (including, for example a CD, a DVD, or a Blu-ray Disc). Examples of the media with a built-in rewriteable non-volatile memory, include but are not limited to memory cards; and media with a built-in ROM, including but not limited to ROM cassettes; etc. Furthermore, various information regarding stored images, for example, property information, may be stored in any other form, or it may be provided in other ways.

The term code, as used above, may include software, firmware, and/or microcode, and may refer to programs, routines, functions, classes, data structures, and/or objects. Shared processor hardware encompasses a single microprocessor that executes some or all code from multiple modules. Group processor hardware encompasses a microprocessor that, in combination with additional microprocessors, executes some or all code from one or more modules. References to multiple microprocessors encompass multiple microprocessors on discrete dies, multiple microprocessors on a single die, multiple cores of a single microprocessor, multiple threads of a single microprocessor, or a combination of the above.

Shared memory hardware encompasses a single memory device that stores some or all code from multiple modules. Group memory hardware encompasses a memory device that, in combination with other memory devices, stores some or all code from one or more modules.

The term memory hardware is a subset of the term computer-readable medium. The term computer-readable medium, as used herein, does not encompass transitory electrical or electromagnetic signals propagating through a medium (such as on a carrier wave); the term computer-readable medium is therefore considered tangible and non-transitory. Non-limiting examples of the non-transitory computer-readable medium include, but are not limited to, rewriteable non-volatile memory devices (including, for example flash memory devices, erasable programmable read-only memory devices, or a mask read-only memory devices); volatile memory devices (including, for example static random access memory devices or a dynamic random access memory devices); magnetic storage media (including, for example an analog or digital magnetic tape or a hard disk drive); and optical storage media (including, for example a CD, a DVD, or a Blu-ray Disc). Examples of the media with a built-in rewriteable non-volatile memory, include but are not limited to memory cards; and media with a built-in ROM, including but not limited to ROM cassettes; etc. Furthermore, various information regarding stored images, for example, property information, may be stored in any other form, or it may be provided in other ways.

The apparatuses and methods described in this application may be partially or fully implemented by a special purpose computer created by configuring a general purpose computer to execute one or more particular functions embodied in computer programs. The functional blocks and flowchart elements described above serve as software specifications, which can be translated into the computer programs by the routine work of a skilled technician or programmer.

Although described with reference to specific examples and drawings, modifications, additions and substitutions of example embodiments may be variously made according to the description by those of ordinary skill in the art. For example, the described techniques may be performed in an order different with that of the methods described, and/or components such as the described system, architecture, devices, circuit, and the like, may be connected or combined to be different from the above-described methods, or results may be appropriately achieved by other components or equivalents.

Although the present invention has been shown and described with respect to certain example embodiments, equivalents and modifications will occur to others skilled in the art upon the reading and understanding of the specification. The present invention includes all such equivalents and modifications and is limited only by the scope of the appended claims.

Although the present invention has been disclosed in the form of preferred embodiments and variations thereon, it will be understood that numerous additional modifications and variations could be made thereto without departing from the scope of the present invention.

What is claimed is:

1. A reconstruction network for reconstructing cine MRI images, the reconstruction network being a variational network configured to reconstruct images from cine MRI data, the reconstruction network comprising:
an architecture with a cascade of cascade modules, wherein
an input of a first cascade module is an input-stack of a plurality of N frames, and
an input of each cascade module, following the first cascade module, is the input-stack and an output-stack of a preceding cascade module; and
a selection unit configured to select, as a basis for an output dataset, a single frame being processed by the cascade modules and that corresponds to an i-th frame of the input-stack.

2. The reconstruction network according to claim 1, wherein
each cascade module includes a convolutional neural network configured to create output images from input images, the input images being processed by the convolutional neural network using at least one of a temporal or spatial convolution, and then being converted into k-space frames,
the convolutional neural network is a U-net or a V-net,
each cascade module includes a data consistency module working parallel to the convolutional neural network, and
outputs of the data consistency module and the convolutional neural network are combined with the input to the cascade module.

3. The reconstruction network according to claim 1, further comprising at least one of:
an image reconstruction module configured to
receive the single frame selected by the selection unit, and
reconstruct an image based on the single frame, or a loss module configured to
receive a reference frame and the single frame selected by the selection unit, and
calculate a loss based on a comparison between data based on the single frame and the reference frame.

4. The reconstruction network according to claim 1, wherein the reconstruction network is trained according to a method comprising:
recording a plurality of MRI dataframes in a time period, wherein the plurality of MRI dataframes show a region of interest at different points of time,
selecting a subset of N training-frames consecutive in time from the plurality of MRI dataframes as an input-stack, inputting the subset of N training-frames into the reconstruction network and generating an output dataset based on a single frame chosen by the selection unit of the reconstruction network,
computing a loss based on the output dataset and updating parameters of the reconstruction network based on the loss,
selecting a further subset of N training-frames consecutive in time from the plurality of MRI dataframes, and repeating the inputting, the generating, the computing, the updating and the selecting until a termination condition is reached.

5. A reconstruction method for reconstructing cine MRI images with the reconstruction network according to claim 1, the reconstruction method comprising:
recording a plurality of MRI dataframes from a region of interest at different points in time, wherein the region of interest includes a heart;
forming the input-stack from a temporally last recorded plurality of N MRI dataframes;
inputting the input-stack into the reconstruction network and reconstructing an image from a single frame chosen by the selection unit of the reconstruction network;
displaying the image; and
in case there is another recorded MRI dataframe, repeating the forming, the inputting, the reconstructing and the displaying until a termination condition is reached.

6. A training method for training the reconstruction network according to claim 1, the training method comprising:
recording a plurality of MRI dataframes in a time period, wherein the plurality of MRI dataframes show a region of interest at different points in time;
selecting a subset of N training-frames consecutive in time from the plurality of MRI dataframes as an input-stack;
inputting the subset of training-frames into the reconstruction network and generating an output dataset based on a single frame chosen by the selection unit of the reconstruction network;
computing a loss based on the output dataset and updating parameters of the reconstruction network based on the loss;
selecting a further subset of N training-frames consecutive in time from the plurality of MRI dataframes; and
repeating the inputting, the generating, the computing, the updating and the selecting until a termination condition is reached.

7. The training method according to claim 6, wherein the plurality of MRI dataframes are processed to be under-sampled by a factor F and the subset of N training-frames is selected from the under-sampled MRI dataframes, and wherein a temporally varying under-sampling pattern is used for each frame.

8. The training method according to claim 6, wherein for the subset of N training-frames, N is between 7 and 14.

9. The training method according to claim 6, wherein each selected single frame has a same relative position in the respective subset of N training-frames, and wherein the selected single frame corresponds to a newest training-frame in the subset.

10. The training method according to claim 6, wherein a first selected subset of N training-frames starts with a frame of the plurality of MRI dataframes, and subsequent subsets of N training frames start with a second frame of a respective preceding subset of N training-frames.

11. The training method according to claim 6, wherein the reconstruction network comprises:
a reconstruction module configured to reconstruct an image from a selected single frame, wherein
the loss is computed based on a comparison between a reconstructed image of the plurality of MRI dataframes and the image reconstructed from the selected single frame.

12. An MRI-System comprising a reconstruction network according to claim 1.

13. An MRI system comprising multiple reconstruction networks according to claim 1, wherein
the selection unit of each of the multiple reconstruction networks is configured to select single frames at different positions of processed stacks,
each of the multiple reconstruction networks comprises a selection unit configured to select single frames at an individual constant position of processed stacks, and
the MRI system further comprises a user interface configured to enable a user to choose between positions of the selected single frames by choosing between given positions or between given latency times.

14. A non-transitory computer program product comprising instructions that, when executed by a computer, cause the computer to carry out the reconstruction method according to claim 5.

15. A non-transitory computer-readable storage medium comprising instructions that, when executed by a computer, cause the computer to perform the training method of claim 6.

16. The training method according to claim 6, wherein for the subset of N training-frames, N is at least one of greater than 4 or less than 30.

17. The training method according to claim 6, wherein each selected single frame has a same relative position in the respective subset of N training-frames.

18. The training method according to claim 6, wherein each selected single frame has a same relative position in the respective subset of N training-frames, and wherein each selected single frame is a training-frame from a temporally last third of the subset of N training-frames.

19. The training method according to claim 6, wherein each selected single frame has a same relative position in the respective subset of N training-frames, and wherein there are not more than 5 training-frames temporally following a training-frame corresponding to the selected single frame.

20. An MRI system comprising a reconstruction network trained according to the training method of claim 6.

21. A non-transitory computer-readable storage medium comprising instructions that, when executed by a computer, cause the computer to perform the reconstruction method according to claim 5.
